(19) United States
(12) Patent Application Publication
(10) Pub. No.: US 2025/0194349 A1
(43) Pub. Date: Jun. 12, 2025

(54) DISPLAY APPARATUS AND METHOD OF MANUFACTURING THE SAME

(71) Applicant: Samsung Display Co., Ltd., Yongin-Si (KR)

(72) Inventor: Hyuneok Shin, Yongin-si (KR)

(21) Appl. No.: 18/972,195

(22) Filed: Dec. 6, 2024

(30) Foreign Application Priority Data
Dec. 7, 2023 (KR) 10-2023-0176773

(51) Int. Cl. H10K 59/122; H10K 59/12; H10K 59/80

(52) U.S. Cl. CPC H10K 59/122; H10K 59/1201; H10K 59/8792

(57) ABSTRACT

A display apparatus includes a first sub-pixel electrode, a spacer including a first opening overlapping the first sub-pixel electrode, wherein the spacer surrounds the first sub-pixel electrode, a first intermediate layer disposed in the first opening of the spacer and overlapping the first sub-pixel electrode, and a first opposite electrode disposed on the first intermediate layer, wherein the spacer includes a structure in which an insulating layer, a light-absorption layer, and a bank layer are sequentially stacked.

### CROSS-REFERENCE TO RELATED APPLICATION

This application is based on and claims priority under 35 U.S.C. § 119 to Korean Patent Application No. 10-2023-0176773, filed on Dec. 7, 2023, in the Korean Intellectual Property Office, the disclosure of which is incorporated by reference herein in its entirety.

### BACKGROUND

### Field

One or more embodiments relate to a structure of a display apparatus and a method of manufacturing the display apparatus.

### Description of the Related Art

A display apparatus visually displays data. The display apparatus may include a substrate divided into a display area and a peripheral area. The display area generally includes scan lines, data lines, and a plurality of sub-pixels. Each sub-pixel may include a thin-film transistor and a pixel electrode electrically connected to the thin-film transistor. In addition, an electrode opposite the pixel electrodes may be provided in the display area, wherein the opposite electrode is common to all the sub-pixels. The peripheral area may include various wirings, a scan driver, a data driver, a controller, a pad portion, and the like, configured to transfer electrical signals to the display area.

Display apparatuses are used in diverse applications, and attempts have been made to design a display apparatus with improved quality.

### SUMMARY

One or more embodiments disclosed herein include a display apparatus with improved resolution, capable of implementing excellent image quality. However, such a technical objective is just an example, and the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a first sub-pixel electrode, a spacer including a first opening overlapping the first sub-pixel electrode, wherein the spacer surrounds the first sub-pixel electrode in a plan view, a first intermediate layer disposed in the first opening of the spacer and overlapping the first sub-pixel electrode, and a first opposite electrode disposed on the first intermediate layer, wherein the spacer includes a structure in which an insulating layer, a light-absorption layer, and a bank layer are sequentially stacked.

The insulating layer may cover a lateral surface of the first intermediate layer.

The insulating layer may cover an edge of the first sub-pixel electrode and be in contact with the first opposite electrode.

The light-absorption layer may cover an upper surface of the insulating layer.

An angle formed by the lateral surface of the first intermediate layer with respect to a bottom surface of the first intermediate layer may be about 50° to about 90°.

The display apparatus may further include a second sub-pixel electrode arranged to be adjacent to the first sub-pixel electrode, a second intermediate layer disposed in a second opening of the spacer and overlapping the second sub-pixel electrode, and a second opposite electrode disposed on the second intermediate layer.

The first opposite electrode and the second opposite electrode may be integrally provided.

The insulating layer and the light-absorption layer may be arranged to extend from a region overlapping a lateral surface of the first intermediate layer to a region overlapping a lateral surface of the second intermediate layer.

The bank layer may be disposed on the light-absorption layer and may fill a step difference formed by the first intermediate layer and the second intermediate layer.

The light-absorption layer may include molybdenum-tantalum oxide (MTO) or molybdenum oxide (MoOₓ).

The light-absorption layer may have a thickness of about 500 Å to about 3000 Å.

The light-absorption layer may include silicon carbide (SiC).

The insulating layer and the bank layer may include different materials from each other.

The insulating layer may include at least one of silicon nitride (SiNₓ), silicon oxide (SiOₓ), and silicon oxynitride (SiOₓN_{y}).

The bank layer may include at least one of hexamethyldisiloxane (HMDSO) and an acrylic monomer.

According to one or more embodiments, a method of manufacturing a display apparatus includes forming a first sub-pixel electrode and a second sub-pixel electrode adjacent to the first sub-pixel electrode, forming a first intermediate layer disposed on the first sub-pixel electrode, and a second intermediate layer disposed on the second sub-pixel electrode, forming a spacer disposed between the first intermediate layer and the second intermediate layer, and forming a first opposite electrode disposed on the first intermediate layer, and a second opposite electrode disposed on the second intermediate layer, wherein the forming of the spacer includes forming an insulating layer covering an edge of the first sub-pixel electrode and an edge of the second sub-pixel electrode, forming a light-absorption layer on the insulating layer, and forming a bank layer on the light-absorption layer.

The method may further include, between the forming of the first intermediate layer and the second intermediate layer and the forming of the spacer, forming a first protective layer disposed on the first intermediate layer and a second protective layer disposed on the second intermediate layer.

The forming of the spacer may include depositing the insulating layer to cover from an upper surface of the first protective layer, through a lateral surface of the first intermediate layer and a lateral surface of the second intermediate layer, to an upper surface of the second protective layer, and depositing the light-absorption layer on an upper surface of the insulating layer to overlap the upper surface of the first protective layer, the lateral surface of the first intermediate layer, the lateral surface of the second intermediate layer, and the upper surface of the second protective layer.

The forming of the spacer may include forming a photoresist on the light-absorption layer to be disposed between the first intermediate layer and the second intermediate layer, etching a portion of the insulating layer and a portion of the light-absorption layer that do not overlap the photoresist, and removing the photoresist.

The bank layer may be disposed on the light-absorption layer and be formed to fill a step difference of the first intermediate layer and the second intermediate layer.

The method may further include, between the forming of the spacer and the forming of the first opposite electrode and the second opposite electrode, removing the first protective layer and the second protective layer.

The first opposite electrode and the second opposite electrode may be integrally formed.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a schematic perspective view of a display apparatus according to an embodiment of the present disclosure.

FIGS. 2A and 2B are schematic equivalent circuit diagrams of a light-emitting diode corresponding to one of the sub-pixels of a display apparatus and a sub-pixel circuit electrically connected to the corresponding light-emitting diode, according to respective embodiments of the present disclosure.

FIG. 3 is a schematic plan view of a portion of a display apparatus according to an embodiment of the present disclosure.

FIG. 4 is a schematic cross-sectional view of a portion of a display apparatus according to an embodiment of the present disclosure.

FIG. 5 is a cross-sectional view of a stack structure of a light-emitting diode according to an embodiment of the present disclosure.

FIGS. 6A, 6B, 60, 6D, 6E, 6F, and 6G are schematic cross-sectional views showing structures formed during a process of manufacturing a display apparatus, according to an embodiment of the present disclosure.

### DETAILED DESCRIPTION

Embodiments, examples of which are illustrated in the accompanying drawings, are described in detail below. In this regard, embodiments in accordance with the present disclosure may have different forms and should not be construed as being limited to the detailed descriptions set forth herein. Accordingly, example embodiments are described below merely to explain aspects of the present disclosure.

Hereinafter, embodiments will be described with reference to the accompanying drawings, wherein like reference numerals refer to like elements throughout and repeated descriptions thereof may be omitted.

As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While such terms as “first” and “second” may be used to describe various components, such components must not be limited to the above terms. The above terms are merely used to distinguish one component from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

It will be further understood that a layer, region, or element referred to as being “on” another layer, region, or element can be directly or indirectly on the other layer, region, or element. That is, for example, intervening layers, regions, or elements may be present.

Sizes of elements in the drawings may be exaggerated or reduced for convenience of explanation or illustration. As an example, the size and thickness of each element shown in the drawings may be arbitrarily represented, and thus, the disclosure is not necessarily limited thereto.

An embodiment described herein as having a specific process order may, unless expressly stated otherwise, be performed in an order different from the described order. As an example, two processes successively described may be simultaneously performed or performed in the opposite order.

A layer, region, or element described herein as being “connected” to another layer, region, or element may be “directly connected” to the other layer, region, or element or may be “indirectly connected” to the other layer, region, or element with one or more other layers, regions, or elements located therebetween. For example, a layer, region, or element referred to herein as being “electrically connected” to another layer, region, or element may be “directly electrically connected” to the other layer, region, or element or may be “indirectly electrically connected” to other layer, region, or element with another layer, region, or element disposed therebetween.

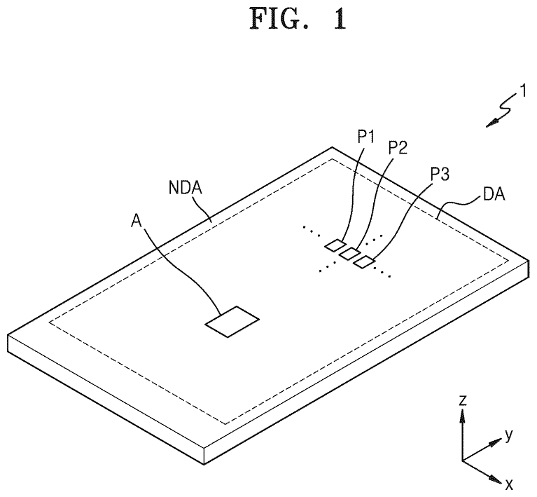

FIG. 1 is a schematic perspective view of a display apparatus 1 according to an embodiment.

Referring to FIG. 1, the display apparatus 1 may include a display area DA and a non-display area NDA outside the display area DA. The display area DA may display images using a first sub-pixel P1, a second sub-pixel P2, and a third sub-pixel P3, which are arranged in the display area DA. A non-display area NDA is outside the display area DA and does not display images. The non-display area NDA may surround the display area DA entirely. The non-display area NDA may contain a driver and the like configured to provide electrical signals or power to the display area DA. The non-display area NDA may also contain a pad, which is a region to which electronic elements or a printed circuit board may be electrically connected.

FIG. 1 show an embodiment in which the display area DA is a polygon (e.g., a quadrangle) having a length in an x direction that is less than a length thereof in a y direction. Alternatively, the display area DA of the display apparatus 1 may be a polygon (e.g., a quadrangle) in which a length thereof in the y direction is less than a length thereof in the x direction in another embodiment. More generally, embodiments are not limited to having the display area DA be an approximate quadrangle. As another embodiment, the display area DA may have various shapes such as an N-gon (where N is a natural number of 3 or more), a circle, or an ellipse. Further, although FIG. 1 shows the display area DA has a shape in which each corner of the display area DA includes a vertex at which a straight line meets a straight line, the display area DA in other embodiments may have rounded corners.

The display apparatus 1 may be used various products including televisions, notebook computers, monitors, advertisement boards, Internet of things (IoTs) as well as portable electronic apparatuses including mobile phones, smartphones, tablet personal computers (PCs), mobile communication terminals, electronic organizers, electronic books, portable multimedia players (PMPs), navigations, and ultra mobile personal computers (UMPCs). In addition, the display apparatus 1 may be used in wearable devices including smartwatches, watchphones, glasses-type displays, and head-mounted displays (HMDs). In addition, in some embodiments, the display apparatus 1 may be employed in a display screen in instrument panels for automobiles, center fascias for automobiles, or center information displays (CIDs) arranged on a dashboard, room mirror displays that replace side mirrors of automobiles, and displays of an entertainment system arranged on the backside of front seats for passengers in backseats of automobiles.

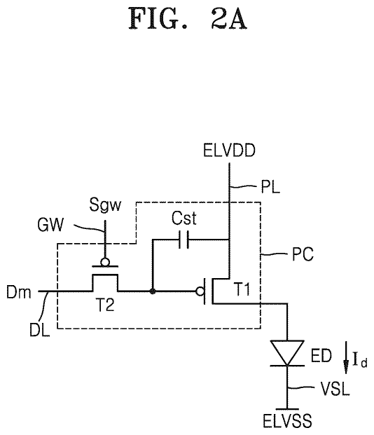

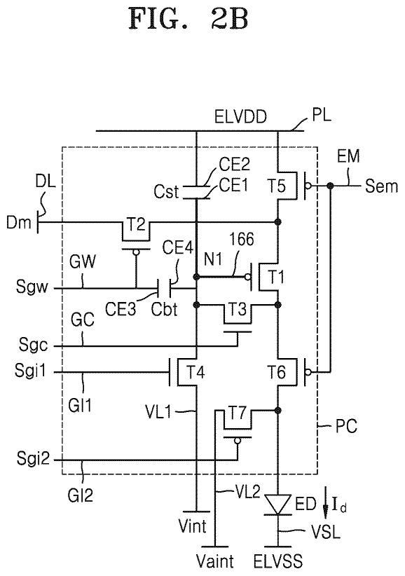

FIGS. 2A and 2B are schematic equivalent circuit diagrams of respective sub-pixel circuits electrically connected to a relevant light-emitting diode in a sub-pixel according to alternative example embodiments.

Referring to FIG. 2A, a light-emitting diode ED may be electrically connected to a sub-pixel circuit PC, and the sub-pixel circuit PC may include a first transistor T1, a second transistor T2, and a storage capacitor Cst. A sub-pixel electrode (e.g., an anode) of the light-emitting diode ED may be electrically connected to the first transistor T1, and an opposite electrode (e.g., a cathode) of the light-emitting diode ED may be electrically connected to an auxiliary line VSL and may receive a voltage corresponding to a common voltage ELVSS through the auxiliary line VSL.

The second transistor T2 is configured to transfer a data signal Dm to the first transistor T1 according to a scan signal Sgw input through a scan line GW, while the data signal Dm is input through a data line DL.

The storage capacitor Cst may be connected to the second transistor T2 and a driving voltage line PL and may be configured to store a voltage corresponding to a difference between a voltage from the second transistor T2 and a driving voltage ELVDD supplied to the driving voltage line PL.

The first transistor T1 may be connected to the driving voltage line PL and the storage capacitor Cst and may be configured to control a driving current I_{d} according to the voltage stored in the storage capacitor Cst. The driving current I_{d} flows from the driving voltage line PL to the light-emitting diode ED. The light-emitting diode ED may be configured to emit light having a preset brightness corresponding to the driving current I_{d}.

Although FIG. 2A illustrates an example embodiment in which the sub-pixel circuit PC includes two transistors and one storage capacitor, embodiments are not limited thereto. For example, FIG. 2B illustrates an embodiment in which the sub-pixel circuit PC includes seven transistors and two capacitors.

Referring to FIG. 2B, the sub-pixel circuit PC may include first to seventh transistors T1, T2, T3, T4, T5, T6, and T7, a storage capacitor Cst, and a boost capacitor Cbt. (In another embodiment similar to the embodiment of FIG. 2B, the sub-pixel circuit PC may not include the boost capacitor Cbt.) The pixel circuit PC of FIG. 2B connects to a sub-pixel electrode (e.g., an anode) of the light-emitting diode ED. In particular, the first transistor T1 may be electrically connected through the sixth transistor T6 to the sub-pixel electrode of the light-emitting diode ED, and an opposite electrode (e.g., a cathode) of the light emitting diode ED may be electrically connected to the auxiliary line VSL and may receive a voltage corresponding to the common voltage ELVSS through the auxiliary line VSL.

Some of the transistors T1, T2, T3, T4, T5, T6, and T7 may be n-channel metal oxide semiconductor (NMOS) field-effect transistors (n-channel MOSFETs), and the rest may be p-channel metal oxide semiconductor (PMOS) field-effect transistors (p-channel MOSFETs). In the embodiment shown in FIG. 2B, the third and fourth transistors T3 and T4 may be n-channel MOSFETs, and the rest may be p-channel MOSFETs. As an example, the third and fourth transistors T3 and T4 may be n-channel MOSFETs including an oxide-based semiconductor material, and the rest of the transistors may be p-channel MOSFETs including a silicon-based semiconductor material. In another embodiment, the third, fourth, and seventh transistors T3, T4, and T7 may be n-channel MOSFETs, and the rest of the transistors may be p-channel MOSFETs.

The first to seventh transistors T1, T2, T3, T4, T5, T6, and T7, the storage capacitor Cst, and the boost capacitor Cbt may be connected to signal lines. The signal lines may include an emission control line EM, a compensation gate line GC, a first initialization gate line GI1, a second initialization gate line GI2, and the data line DL. The sub-pixel circuit PC may be electrically connected to one or more voltage lines, for example, the driving voltage line PL, a first initialization voltage line VL1, and a second initialization voltage line VL2.

The first transistor T1 may be a driving transistor. A gate electrode of the first transistor T1 may be connected to the storage capacitor Cst, a first electrode of the first transistor T1 may be electrically connected to the driving voltage line PL through the fifth transistor T5, and a second electrode of the first transistor T1 may be electrically connected to a first electrode (e.g., an anode) of the light-emitting diode ED through the sixth transistor T6. One of the first electrode and the second electrode of the first transistor T1 may be a source electrode, and the other may be a drain electrode. The first transistor T1 may be configured to supply the driving current la to the light-emitting diode ED according to a switching operation of the second transistor T2.

The second transistor T2 may be a switching transistor. A gate electrode of the second transistor T2 is connected to the scan line GW, a first electrode of the second transistor T2 is connected to the data line DL, and a second electrode of the second transistor T2 is connected to the first electrode of the first transistor T1 and electrically connected to the driving voltage line PL through the fifth transistor T5. One of the first electrode and the second electrode of the second transistor T2 may be a source electrode, and the other may be a drain electrode. The second transistor T2 may be turned on according to a scan signal Sgw transferred through the scan line GW and may perform a switching operation of transferring a data signal Dm from the data line DL to the first electrode of the first transistor T1.

The third transistor T3 may be a compensation transistor configured to compensate for a threshold voltage of the first transistor T1. A gate electrode of the third transistor T3 is connected to a compensation gate line GC. A first electrode of the third transistor T3 is connected through a node connection line 166 to a lower electrode CE1 of the storage capacitor Cst and to the gate electrode of the first transistor T1. A first electrode of the third transistor T3 may also be connected to the fourth transistor T4. A second electrode of the third transistor T3 is connected to the second electrode of the first transistor T1 and electrically connected to the first electrode (e.g., the anode) of the light-emitting diode ED through the sixth transistor T6. One of the first electrode and the second electrode of the third transistor T3 may be a source electrode, and the other may be a drain electrode.

The third transistor T3 is turned on according to a compensation signal Sgc transferred through the compensation gate line GC, and when turned on, the third transistor diode-connects the first transistor T1 by electrically connecting the gate electrode and the second electrode (e.g., a drain electrode) of the first transistor T1.

The fourth transistor T4 may be a first initialization transistor configured to initialize the gate electrode of the first transistor T1. A gate electrode of the fourth transistor T4 is connected to a first initialization gate line GI1. A first electrode of the fourth transistor T4 is connected to the first initialization voltage line VL1. A second electrode of the fourth transistor T4 may be connected to the lower electrode CE1 of the storage capacitor Cst, the first electrode of the third transistor T3, and the gate electrode of the first transistor T1. One of the first electrode and the second electrode of the fourth transistor T4 may be a source electrode, and the other may be a drain electrode. The fourth transistor T4 may be turned on according to a first initialization signal Sgi1 transferred through the first initialization gate line GI1 and may perform an initialization operation of initializing the voltage of the gate electrode of the first transistor T1 by transferring a first initialization voltage Vint to the gate electrode of the driving transistor T1.

The fifth transistor T5 may be an operation control transistor. A gate electrode of the fifth transistor T5 is connected to the emission control line EM, a first electrode of the fifth transistor T5 is connected to the driving voltage line PL, and a second electrode of the fifth transistor T5 is connected to the first electrode of the first transistor T1 and the second electrode of the second transistor T2. One of the first electrode and the second electrode of the fifth transistor T5 may be a source electrode, and the other may be a drain electrode.

The sixth transistor T6 may be an emission control transistor. A gate electrode of the sixth transistor T6 is connected to the emission control line EM, a first electrode of the sixth transistor T6 is connected to the second electrode of the first transistor T1 and the second electrode of the third transistor T3, and a second electrode of the sixth transistor T6 is electrically connected to a second electrode of the seventh transistor T7 and the first electrode (e.g., the anode) of the light-emitting diode ED. One of the first electrode and the second electrode of the sixth transistor T6 may be a source electrode, and the other may be a drain electrode.

The fifth transistor T5 and the sixth transistor T6 may be simultaneously turned on according to an emission control signal Sem transferred through the emission control line EM. When the fifth transistor and the sixth transistor are turned on, the driving voltage ELVDD is transferred to the light-emitting diode ED, and the driving current I_{d} flows through the light-emitting diode ED.

The seventh transistor T7 may be a second initialization transistor configured to initialize the first electrode (e.g., the anode) of the light-emitting diode ED. A gate electrode of the seventh transistor T7 is connected to the second initialization gate line GI2. A first electrode of the seventh transistor T7 is connected to the second initialization voltage line VL2. A second electrode of the seventh transistor T7 is connected to the second electrode of the sixth transistor T6 and the first electrode (e.g., the anode) of the light-emitting diode ED. The seventh transistor T7 may be turned on according to a second initialization signal Sgi2 transferred through the second initialization gate line GI2, and the seventh transistor may be configured to initialize the first electrode of the light-emitting diode ED by transferring a second initialization voltage Vaint from the second initialization voltage line VL2 to the first electrode (e.g., the anode) of the light-emitting diode ED.

In an embodiment, the second initialization voltage line VL2 may be a next scan line. As an example, the second initialization gate line GI2 connected to the seventh transistor T7 of the sub-pixel circuit PC and arranged in an i-th row (i being a natural number), may correspond to a scan line of the sub-pixel circuit PC arranged in an (i+1)-th row. In another embodiment, the second initialization voltage line VL2 may be the emission control line EM. As an example, the emission control line EM may be electrically connected to the fifth to seventh transistors T5, T6, and T7.

The storage capacitor Cst includes the lower electrode CE1 and an upper electrode CE2. The lower electrode CE1 of the storage capacitor Cst is connected to the gate electrode of the first transistor T1, and the upper electrode CE2 of the storage capacitor Cst is connected to the driving voltage line PL. The storage capacitor Cst may be configured to store charge corresponding to a difference between a voltage of the gate electrode of the first transistor T1 and the driving voltage ELVDD.

The boost capacitor Cbt includes a third electrode CE3 and a fourth electrode CE4. The third electrode CE3 may be connected to the scan line GW and the gate electrode of the second transistor T2, and the fourth electrode CE4 may be connected to the node connection line 166 and the first electrode of the third transistor T3. The boost capacitor Cbt may raise the voltage of a first node N1 when a scan signal Sgw supplied to the scan line GW is a turn-off voltage. When the voltage of the first node N1 is raised, the first transistor T1 may be fully turned off the driving current I_{d}, so that the light-emitting diode ED may clearly express a black grayscale.

The first node N1 may be a region where the gate electrode of the first transistor T1, the first electrode of the third transistor T3, the second electrode of the fourth transistor T4, and the fourth electrode CE4 of the boost capacitor Cbt are connected to each other.

In the embodiment of FIG. 2B, the third and fourth transistors T3 and T4 are n-channel MOSFETs, and the first, second, fifth to seventh transistors T1, T2, T5, T6, and T7 are p-channel MOSFETs. The first transistor T1, which directly influences the brightness of the display apparatus displaying images, may be configured to include a semiconductor layer including polycrystalline silicon having high reliability, and thus, a high-resolution display apparatus may be implemented through this configuration.

Although the embodiment of FIG. 2B provides an example of the sub-pixel circuit PC in which some of the transistors are NMOSFETs and the rest are PMOSFETs, embodiments are not limited thereto. In another embodiment, the sub-pixel circuit PC includes three transistors, and all of the three transistors may be NMOSFETs. However, various modifications may be made.

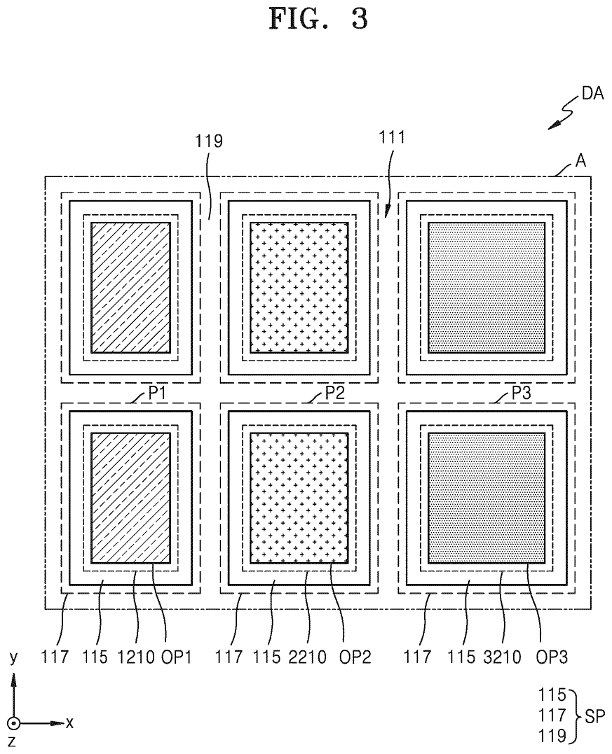

FIG. 3 is a schematic plan view of a portion of the display apparatus according to an embodiment. Specifically, FIG. 3 is an enlarged schematic plan view of an embodiment of a region A in the display area DA of the display apparatus 1 shown in FIG. 1.

Referring to FIG. 3, a plurality of sub-pixels may be arranged in the display area DA of the display apparatus 1. The plurality of sub-pixels may include a first sub-pixel P1, a second sub-pixel P2, and a third sub-pixel P3. The first sub-pixel P1, the second sub-pixel P2, and the third sub-pixel P3 may be sub-pixels configured to emit light of different colors. As an example, the first sub-pixel P1 may be a pixel configured to emit red light, the second sub-pixel P2 may be a pixel configured to emit blue light, and the third sub-pixel P3 may be a pixel configured to emit green light. Red light may be light in a wavelength band of about 580 nm to about 780 nm, blue light may be light in a wavelength band of about 400 nm to about 495 nm, and green light may be light in a wavelength band of about 495 nm to about 580 nm.

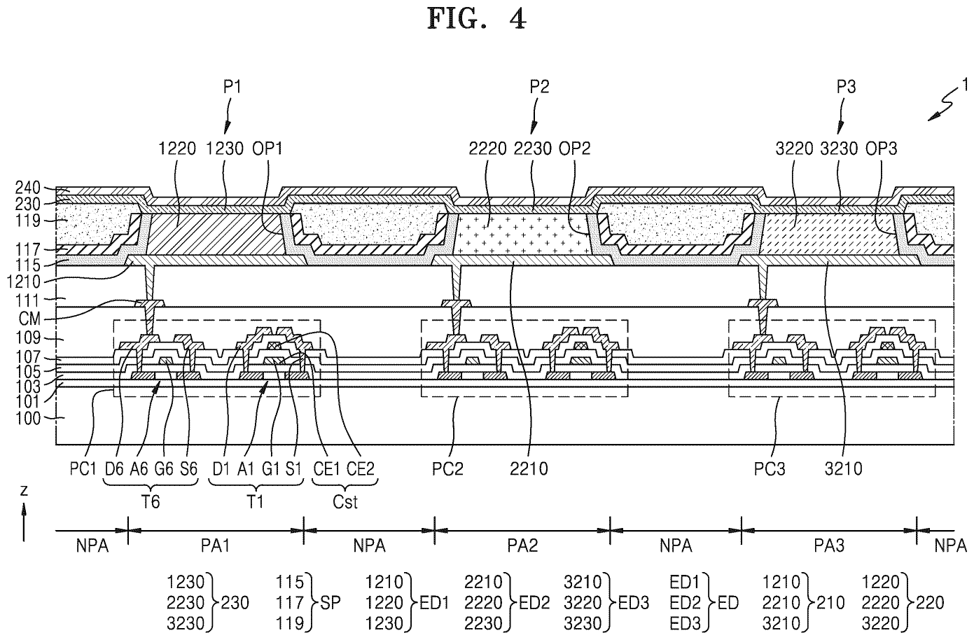

Each of the plurality of sub-pixels may include an organic light-emitting diode, and the organic light-emitting diode may include a sub-pixel electrode, an opposite electrode, and an intermediate layer therebetween. Accordingly, the first sub-pixel P1 may include a first sub-pixel electrode 1210, the second sub-pixel P2 may include a second sub-pixel electrode 2210, and the third sub-pixel P3 may include a third sub-pixel electrode 3210. The first sub-pixel electrode 1210, the second sub-pixel electrode 2210, and the third sub-pixel electrode 3210 may be apart from each other on a plane. In the present specification, “on a plane” refers to a plane viewed from a direction perpendicular to a substrate 100 (see FIG. 4). That is, “A and B apart from each other on a plane” means “A and B are apart or separated from each other when viewed in a direction perpendicular to the substrate 100.”

A spacer SP may surround each of the sub-pixels. That is, the spacer SP may surround the first sub-pixel electrode 1210, the second sub-pixel electrode 2210, and the third sub-pixel electrode 3210. Although described in more detail with reference to FIG. 4, the spacer SP may include a structure in which an insulating layer 115, a light-absorption layer 117, and a bank layer 119 are sequentially stacked, and the insulating layer 115 of the spacer SP may cover an edge or perimeter of each of the first sub-pixel electrode 1210, the second sub-pixel electrode 2210, and the third sub-pixel electrode 3210. In particular, the spacer SP may include a plurality of openings in which organic light-emitting diodes of the sub-pixels may be disposed. As an example, the spacer SP may include a first opening OP1 overlapping the first sub-pixel electrode 1210, a second opening OP2 overlapping the second sub-pixel electrode 2210, and a third opening OP3 overlapping the third sub-pixel electrode 3210. Although not shown in FIG. 3, emission layers configured to emit light may be respectively arranged inside the first opening OP1, the second opening OP2, and the third opening OP3 of the spacer SP, and an opposite electrode may be disposed on the emission layers. As described above, a stack structure including the sub-pixel electrode, the emission layer, and the opposite electrode may form one organic light-emitting diode. That is, one opening of the spacer SP may correspond to one organic light-emitting diode and define an emission area.

Each of the first opening OP1, the second opening OP2, and the third opening OP3 may have a polygonal shape when viewed in a direction (e.g., a z axis direction) perpendicular to the substrate 100 (see FIG. 4). Although each of the first opening OP1, the second opening OP2, and the third opening OP3 has a quadrangular shape in a plan view shown in FIG. 3, embodiments are not limited thereto. As an example, each of the first opening OP1, the second opening OP2, and the third opening OP3 may have a circular shape or an elliptical shape in a plan view.

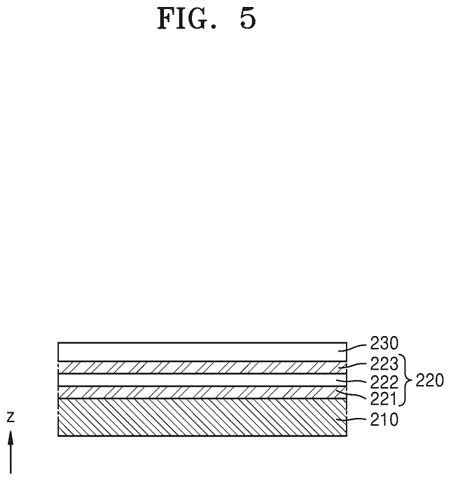

FIG. 4 is a schematic cross-sectional view of the display apparatus 1 according to an embodiment, and FIG. 5 is a cross-sectional view of a stack structure of a light-emitting diode according to an embodiment.

Referring to FIG. 4, the display apparatus 1 may include first to third sub-pixel areas PA1, PA2, and PA3 and include a non-sub-pixel area NPA between the adjacent sub-pixel areas. The planar shape of the display apparatus 1 may be the same as the planar shape of the substrate 100. Accordingly, when the display apparatus 1 includes the first to third sub-pixel areas PA1, PA2, and PA3 and the non-sub-pixel area NPA, the substrate 100 may similarly include the first to third sub-pixel areas PA1, PA2, and PA3 and the non-sub-pixel area NPA.

A sub-pixel circuit PC of the display apparatus 1 may be formed on the substrate 100. The sub-pixel circuit PC may include a first sub-pixel circuit PC1 of the first sub-pixel P1, a second sub-pixel circuit PC2 of the second sub-pixel P2, and a third sub-pixel circuit PC3 of the first sub-pixel P3. Each of the first sub-pixel circuit PC1, the second sub-pixel circuit PC2, and the third sub-pixel circuit PC3 may include the same structure. The first to third sub-pixel circuits PC1, PC2, and PC3 may each include one or more transistors and storage capacitors such as described above with reference to FIG. 2A and 2B. FIG. 4 shows an embodiment in which each of the first to third sub-pixel circuits PC1, PC2, and PC3 including a first transistor T1, a sixth transistor T6, and a storage capacitor Cst, which may be connected to operate as described above with reference to FIG. 2B.

The substrate 100 may include glass or polymer resin. The substrate 100 may have a structure in which a base layer and an inorganic barrier layer are stacked, wherein the base layer includes a polymer resin. The polymer resin may include polyethersulphone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate, cellulose tri acetate (TAC), cellulose acetate propionate (CAP), and the like.

A buffer layer 101 may be disposed on the upper surface of the substrate 100. The buffer layer 101 may prevent impurities from penetrating an overlying semiconductor layer of a transistor. The buffer layer 101 may include an inorganic insulating material such as silicon nitride, silicon oxynitride, and silicon oxide, and may include a single layer or multiple layers including the above inorganic insulating materials.

The first transistor T1 may include a semiconductor layer A1 and a gate electrode G1, wherein the semiconductor layer A1 is on the buffer layer 101, and the gate electrode G1 overlaps a channel region of the first semiconductor layer A1. The semiconductor layer A1 may include a silicon-based semiconductor material, for example, polycrystalline silicon. The semiconductor layer A1 may include a channel region, a first region, and a second region, the first region and the second region being respectively on two opposite sides of the channel region. The first region and the second region may be regions including impurities at a concentration higher than the impurity concentration in the channel region. One of the first region and the second region may correspond to a source region, and the other may correspond to a drain region.

The sixth transistor T6 may include a semiconductor layer A6 and a gate electrode G6, wherein the semiconductor layer A6 is on the buffer layer 101, and the gate electrode G6 overlaps a channel region in the semiconductor layer A6. The semiconductor layer A6 may include a silicon-based semiconductor material, for example, polycrystalline silicon. The semiconductor layer A6 may include a channel region, a first region, and a second region, the first region and the second region being respectively on two opposite sides of the channel region. The first region and the second region may be regions including impurities at a concentration higher than the concentration of impurities in the channel region. One of the first region and the second region may correspond to a source region, and the other may correspond to a drain region.

The gate electrode G1 and the gate electrode G6 may include a conductive material, e.g., one or more of molybdenum (Mo), aluminum (Al), copper (Cu), and titanium (Ti), and may have a single-layer structure or a multi-layer structure including the above materials. A first gate insulating layer 103 may be disposed below the gate electrode G1 and the gate electrode G6, wherein the first gate insulating layer 103 is for electrical insulation between the semiconductor layer A1 and the gate electrode G1 and between the semiconductor layer A6 and the gate electrode G6. The first gate insulating layer 103 may include an inorganic insulating material such as silicon nitride, silicon oxynitride, and silicon oxide, and may include a single layer or multiple layers of the above inorganic insulating materials.

The storage capacitor Cst may include the lower electrode CE1 and the upper electrode CE2 overlapping each other. In an embodiment, the lower electrode CE1 of the storage capacitor Cst may include the gate electrode G1, or the gate electrode G1 may include the lower electrode CE1 of the storage capacitor Cst. As an example, the gate electrode G1 and the lower electrode CE1 of the storage capacitor Cst may be one body.

A first interlayer insulating layer 105 may be disposed between the lower electrode CE1 and the upper electrode CE2 of the storage capacitor Cst. The first interlayer insulating layer 105 may include an inorganic insulating material such as silicon nitride, silicon oxynitride, and silicon oxide, and the interlayer insulating layer 105 may include a single-layer structure or a multi-layer structure including the above inorganic insulating materials.

The upper electrode CE2 of the storage capacitor Cst may include a conductive material of a low-resistance material such as molybdenum (Mo), aluminum (Al), copper (Cu) and/or titanium (Ti), and the upper electrode CE2 may have a single-layer structure or a multi-layer structure including the above materials.

A second interlayer insulating layer 107 may be on the upper electrode CE2 and the first interlayer insulating layer 105. A source electrode S1 and/or a drain electrode D1 may be disposed on the second interlayer insulating layer 107, the source electrode S1 and/or the drain electrode D1 being electrically connected to the semiconductor layer A1 of the first transistor T1. A source electrode S6 and/or a drain electrode D6 may also be disposed on the second interlayer insulating layer 107, the source electrode S6 and/or the drain electrode D6 being electrically connected to the semiconductor layer A6 of the sixth transistor T6. The source electrodes S1 and S6 and/or the drain electrodes D1 and D6 may include aluminum (Al), copper (Cu), titanium (Ti), and/or another conductive material and may include a single layer or multiple layers of the above materials.

A first organic insulating layer 109 may be disposed on the sub-pixel circuit PC. The first organic insulating layer 109 may include an organic insulating material such as acryl, benzocyclobutene (BCB), polyimide, or hexamethyldisiloxane (HMDSO).

A connection metal CM may be disposed on the first organic insulating layer 109. The connection metal CM may include aluminum (Al), copper (Cu), and/or titanium (Ti), and include a single layer or multiple layers including the above materials.

A second organic insulating layer 111 may be disposed between the connection metal CM and a sub-pixel electrode 210. The second organic insulating layer 111 may include an organic insulating material such as acryl, benzocyclobutene (BCB), polyimide, or hexamethyldisiloxane (HMDSO). According to the embodiment shown in FIG. 4, the sub-pixel circuit PC is electrically connected to the sub-pixel electrode 210 through the connection metal CM. Alternatively, the connection metal CM may be omitted, and one organic insulating layer may be located between the sub-pixel circuit PC and the sub-pixel electrode 210. In some other alternative embodiments, three or more organic insulating layers may be located between the sub-pixel circuit PC and the sub-pixel electrode 210, and the sub-pixel circuit PC may be electrically connected to the sub-pixel electrode 210 through a plurality of connection metals.

The first, second, and third sub-pixels P1, P2, and P3 may respectively include first, second, and third light-emitting diodes ED1, ED2, and ED3. The first to third light-emitting diodes ED1, ED2, and ED3 respectively electrically connected to the first to third sub-pixel circuits PC1, PC2, and PC3 may each have a stack structure of the sub-pixel electrode 210, an intermediate layer 220, and an opposite electrode 230.

As an example, the first light-emitting diode ED1 may include a first sub-pixel electrode 1210, a first intermediate layer 1220, and a first opposite electrode 1230. The first sub-pixel electrode 1210 may be electrically connected to the first sub-pixel circuit PC1. The second light-emitting diode ED2 may include a second sub-pixel electrode 2210, a second intermediate layer 2220, and a second opposite electrode 2230. The second sub-pixel electrode 2210 may be electrically connected to the second sub-pixel circuit PC2. The third light-emitting diode ED3 may include a third sub-pixel electrode 3210, a third intermediate layer 3220, and a third opposite electrode 3230. The third sub-pixel electrode 3210 may be electrically connected to the third sub-pixel circuit PC3.

In the example shown in FIG. 4, the first opposite electrode 1230, the second opposite electrode 2230, and the third opposite electrode 3230 may be portions of an integrated layer or region denoted by the opposite electrode 230. In other words, the opposite electrode 230 may include the first opposite electrode 1230, the second opposite electrode 2230, and the third opposite electrode 3230, and the first opposite electrode 1230, the second opposite electrode 2230, and the third opposite electrode 3230 may be electrically connected to each other.

The sub-pixel electrode 210 is sometimes used herein to generically refer to any of the first sub-pixel electrode 1210, the second sub-pixel electrode 2210, and the third sub-pixel electrode 3210. Each sub-pixel electrode 210 may be formed on the second organic insulating layer 111. Each sub-pixel electrode 210 may be a (semi) transparent electrode or a reflective electrode. In the case where the sub-pixel electrode 210 includes a (semi) transparent electrode, the sub-pixel electrode 210 may include indium tin oxide (ITO), indium zinc oxide (IZO), zinc oxide (ZnO), indium oxide (In₂O₃), indium gallium oxide (IGO), or aluminum zinc oxide (AZO). In the case where the sub-pixel electrode 210 includes a reflective electrode, the sub-pixel electrode 210 may include a reflective layer including Ag, Mg, Al, Pt, Pd, Au, Ni, Nd, Ir, Cr, or a compound thereof, and a layer on the reflective layer, the layer including ITO, IZO, ZnO or In₂O₃. In an embodiment, the sub-pixel electrode 210 may have a structure including an ITO layer, an Ag layer, and an ITO layer that are sequentially stacked. Each sub-pixel electrode 210 may be electrically connected to the corresponding connection metal CM through a contact hole extending through the second organic insulating layer 111.

The first sub-pixel electrode 1210, the second sub-pixel electrode 2210, and the third sub-pixel electrode 3210 may each include an inner portion and an outer portion surrounding the inner portion. In the present specification, an “outer portion (or neighboring portion)” of the sub-pixel electrode denotes a portion of the sub-pixel electrode including the edge of the sub-pixel electrode, and an “inner portion of the sub-pixel electrode” denotes another portion of the sub-pixel area surrounded by the outer portion (or neighboring portion).

The intermediate layer 220 may be disposed on each sub-pixel electrode 210. The intermediate layer 220 may be disposed on the inner portion of each sub-pixel electrode 210. The intermediate layer 220 may include the first intermediate layer 1220, the second intermediate layer 2220, and the third intermediate layer 3220, wherein the first intermediate layer 1220 is in the first sub-pixel P1, the second intermediate layer 2220 is in the second sub-pixel P2, and the third intermediate layer 3220 is in the third sub-pixel P3. The first intermediate layer 1220 may be configured to overlap and be in contact with the first sub-pixel electrode 1210, the second intermediate layer 2220 may be configured to overlap and be in contact with the second sub-pixel electrode 2210, and the third intermediate layer 3220 may be configured to overlap and be in contact with the third sub-pixel electrode 3210.

The intermediate layer 220 may include an emission layer 222 as shown in FIG. 5. The intermediate layer 220 may include a common layer disposed between the sub-pixel electrode 210 and the emission layer 222 and/or between the emission layer 222 and the opposite electrode 230. Hereinafter, a common layer disposed between the sub-pixel electrode 210 and the emission layer 222 is referred to as a first common layer 221, and a common layer the emission layer 222 and the opposite electrode 230 is referred to as a second common layer 223.

The emission layer 222 may include a polymer organic material or a low-molecular weight organic material emitting light having a preset color (red, green, or blue). In another embodiment, the emission layer 222 may include an inorganic material or quantum dots. Here, the emission layer of the first intermediate layer 1220, the emission layer of the second intermediate layer 2220, and the emission layer of the third intermediate layer 3220 may be configured to emit light of different colors.

The first common layer 221 may include a hole transport layer (HTL) and/or a hole injection layer (HIL). The second common layer 223 may include an electron transport layer (ETL) and/or an electron injection layer (EIL). The first common layer 221 and the second common layer 223 may each include an organic material.

The intermediate layer 220 may have a single stack structure including a single emission layer, or a tandem structure, which is a multi-stack structure including a plurality of emission layers. In the case where the intermediate layer 220 has a tandem structure, a charge generation layer CGL may be disposed between the plurality of stacks.

The intermediate layer 220 may be formed using a photo patterning process. As an example, to form the first intermediate layer 1220, a first material layer including the same material as the first intermediate layer 1220 may be deposited on the entire surface of the substrate 100 and then a photoresist may be formed on the first material layer to overlap the first sub-pixel electrode 1210. Then, the first intermediate layer 1220 may be patterned and formed by etching a portion of the first material layer using the photoresist as a mask. The same or similar process may be repeated to pattern layers of second and third materials to respectively form the second intermediate layer 2220 and the third intermediate layer 3220 respectively on the second sub-pixel electrode 2220 and the third sub-pixel electrode 3220. In this case, the etching process may include a dry etching process, and the intermediate layer 220 may be a portion left after the etching process. In addition, the photoresist disposed on the intermediate layer 220 may be removed by an ashing process.

Because the intermediate layer 220 in the display apparatus according to an embodiment is formed through photo patterning processes described above, sub-pixels may be small and closely spaced to provide ultra-high-resolution images. In particular, when the intermediate layer 220 is formed through the photo patterning process, a fine metal mask (FMM) used to pattern the intermediate layer 220 may not be required. In contrast, patterning that uses an FMM may require an interval between adjacent sub-pixels to be a specific length or more, which can limit the minimum spacing of the sub-pixels and consequently limit the resolution of displayed images. The display apparatus according to an embodiment may be configured to pattern the intermediate layer 220 using the photoresist without a fine metal mask, so that an interval between adjacent sub-pixels may be remarkably reduced, and thus, ultra high-resolution images may be provided.

The edge or lateral surface of the intermediate layer 220 formed using the photo patterning process may have a shape that is close to vertical. Alternatively, the lateral surface of the intermediate layer 220 may have a forward tapered shape. That is, the width of the bottom surface of the intermediate layer 220 may be similar to or may be a little wider than the width of the upper surface of the intermediate layer 220. In other words, the cross-section of the intermediate layer 220 may have a rectangular or trapezoidal shape. An angle formed by the lateral surface of the intermediate layer 220 with respect to the bottom surface of the intermediate layer 220 may be about 50° to about 90°.

Referring to FIG. 4 again, the spacer SP may overlap the sub-pixel electrode 210. The spacer SP may particularly be disposed on each sub-pixel electrode 210 to cover an outer portion of the sub-pixel electrode 210. As an example, the spacer SP may overlap the outer portion of the sub-pixel electrode 210 and be in direct contact with the upper surface of the second organic insulating layer 111 where the sub-pixel electrode 210 is not present. The spacer SP may cover the lateral surface of each sub-pixel electrode 210.

The spacer SP may be arranged to surround the first sub-pixel P1, the second sub-pixel P2, and the third sub-pixel P3. Specifically, the spacer SP may include a first opening OP1 overlapping the first sub-pixel electrode 1210, a second opening OP2 overlapping the second sub-pixel electrode 2210, and a third opening OP3 overlapping the third sub-pixel electrode 3210. As an example, the first intermediate layer 1220 may be disposed in the first opening OP1, the second intermediate layer 2220 may be disposed in the second opening OP2, and the third intermediate layer 3220 may be disposed in the third opening OP3. In other words, the spacer SP may be arranged in the non-sub-pixel area NPA between the first sub-pixel P1 and the second sub-pixel P2, or the non-sub-pixel area NPA between the second sub-pixel P2 and the third sub-pixel P3. Here, the non-sub-pixel area NPA may denote a region of the display area DA other than the emission areas of the first to third light-emitting diodes ED1, ED2, and ED3.

The spacer SP may have a structure in which the insulating layer 115, the light-absorption layer 117, and the bank layer 119 are sequentially stacked. First, the insulating layer 115 is disposed in the lowermost portion of the triple-layer structure of the spacer SP and may serve to insulate the sub-pixel electrode 210 from the opposite electrode 230. For this purpose, the insulating layer 115 may not only cover the outer portion of the sub-pixel electrode 210 but also cover the lateral surface of the intermediate layer 220 and may be in contact with the opposite electrode 230. That is, the insulating layer 115 may extend from the sub-pixel electrode 210 to the opposite electrode 230 through the intermediate layer 220, in the non-sub-pixel area NPA.

In addition, the insulating layer 115 may be arranged between the first sub-pixel P1 and the second sub-pixel P2 to define areas of the sub-pixels and may separate adjacent light-emitting diodes such that the adjacent light-emitting diodes are driven independently. For this purpose, the insulating layer 115 may extend from the lateral surface of the first intermediate layer 1220 to the lateral surface of the second intermediate layer 2220. As an example, the insulating layer 115 may overlap the lateral surface of the intermediate layer 220 and the outer portion of the sub-pixel electrode 210 and be in direct contact with the upper surface of the second organic insulating layer 111 where the sub-pixel electrode 210 is not present. The insulating layer 115 may cover the lateral surface of each of the sub-pixel electrodes 210.

The insulating layer 115 may include an inorganic insulating material. Using an inorganic insulating material in the insulating layer 115 may prevent or reduce deterioration of the quality of the light-emitting diode that might otherwise be caused by gas emitted from an organic insulating layer, during the process of manufacturing the display apparatus using an organic insulating material in the insulating layer 115. The insulating layer 115 may include an inorganic insulating material such as silicon oxide (SiOₓ), silicon nitride (SiNₓ), or silicon oxynitride (SiOₓN_{y}). In an embodiment, the insulating layer 115 may have a thickness of about 1000 Å to about 3000 Å.

The light-absorption layer 117 included in the triple-layer structure of the spacer SP may be disposed on the insulating layer 115. The light-absorption layer 117 may cover the upper surface of the insulating layer 115. Accordingly, like the insulating layer 115, the light-absorption layer 117 may overlap the lateral surface of the intermediate layer 220. As an example, the light-absorption layer 117 on the insulating layer 115 may overlap the lateral surface of the first intermediate layer 1220 and extend to also overlap the lateral surface of the second intermediate layer 2220.

In an embodiment, the light-absorption layer 117 may include a light-absorption material such as molybdenum-tantalum oxide (MTO) or molybdenum oxide (MoOₓ). In another embodiment, the light-absorption layer 117 may include a light-absorption material such as silicon carbide (SiC). The light-absorption layer 117 may have a thickness of about 500 Å to about 3000 Å. A transmittance of the light-transmission layer 117 including the light-absorption material may be 10% or less. As an example, a transmittance of the light-absorption layer 117 may be about 1%. That is, light emitted from the lateral surfaces of the first to third light-emitting diodes ED1, ED2, and ED3 and incident to the spacer SP may be mostly absorbed by the light-absorption layer 117.

Because the light-absorption layer 117 includes the light-absorption material, the display apparatus according to an embodiment may be configured to increase color purity of light emitted from the area of each of the first to third light-emitting diodes ED1, ED2, and ED3, even if the first to third light-emitting diodes ED1, ED2, and ED3 are closely spaced for displaying ultra high-resolution images. As described above, in the case where the intermediate layer 220 is formed using the photo patterning process, ultra high-resolution images may be implemented. However, when an arrangement interval of the plurality of sub-pixels is reduced to implement ultra high-resolution images in a display apparatus lacking the light-absorption layer 117, light emitted from one of the sub-pixels may be totally reflected and incident to an adjacent sub-pixel, causing color purity to be reduced. In contrast, in the display apparatus according to an embodiment, because the spacer SP includes the light-absorption layer 117, light that may propagate between adjacent sub-pixels may be blocked, and thus, color purity of light emitted from each of the sub-pixels may be improved.

The triple-layer structure of the spacer SP may further include the bank layer 119 disposed on the light-absorption layer 117. Specifically, the bank layer 119 may be formed to cover the upper surface of the light-absorption layer 117 and fill a step difference formed by the intermediate layer 220. As an example, in the case where the intermediate layer 220 is patterned through the photo patterning process, a step difference may occur between the non-sub-pixel area NPA and the first to third sub-pixel areas PA1, PA2, and PA3. A large step difference increases the risk of disconnection in layers deposited later. Therefore, the bank layer 119 may be arranged in the non-sub-pixel area NPA to planarize the upper surface of the structure.

The bank layer 119 may include a different material from that of the insulating layer 115. In an embodiment, the bank layer 119 may include an organic material such as hexamethyldisiloxane (HMDSO) or polyimide (PI). However, embodiments are not limited thereto, and the bank layer 119 may include an organic material such as an acrylic monomer or benzocyclobutene (BCB).

The opposite electrode 230 may be disposed on the intermediate layer 220 and the spacer SP. As described above, a stack structure including one of the sub-pixel electrodes 210, the intermediate layer 220, and the opposite electrode 230 corresponds to a light-emitting diode. The opposite electrode 230 may include the first opposite electrode 1230, the second opposite electrode 2230, and the third opposite electrode 3230, wherein the first opposite electrode 1230 is in the first sub-pixel P1, the second opposite electrode 2230 is in the second sub-pixel P2, and the third opposite electrode 3230 is in the third sub-pixel P3. The first opposite electrode 1230 may be disposed on the first intermediate layer 1220, the second opposite electrode 2230 may be disposed on the second intermediate layer 2220, and the third opposite electrode 3230 may be disposed on the third intermediate layer 3220.

The first opposite electrode 1230, the second opposite electrode 2230, and the third opposite electrode 3230 may be integrally provided within the opposite electrode 230, which may be formed on and covering the entire surface of the substrate 100. That is, the opposite electrode 230 may be also disposed on the spacer SP arranged in the non-sub-pixel area NPA. Because the spacer SP fills the step difference occurring due to the intermediate layer 220 and planarizes the upper surface of the structure on which the opposite electrode 230 is formed, the opposite electrode 230 may overcome the step difference and extend without disconnection.

The opposite electrode 230 may include a conductive material having a low work function. As an example, the opposite electrode 230 may include a (semi) transparent layer including silver (Ag), magnesium (Mg), aluminum (Al), platinum (Pt), palladium (Pd), gold (Au), nickel (Ni), neodymium (Nd), and iridium (Ir), chromium (Cr), lithium (Li), calcium (Ca), or an alloy thereof. Alternatively, the opposite electrode 230 may further include a transparent conductive layer on the (semi) transparent layer, the transparent conductive layer including ITO, IZO, ZnO, or In₂O₃.

A capping layer 240 may be on the opposite electrode 230. The capping layer 400 may improve external light-emission efficiency of the first to third light-emitting diodes ED1, ED2, and ED3 based on the principle of constructive interference. The capping layer 240 may be an organic capping layer including an organic material, an inorganic capping layer including an inorganic material, or a composite capping layer including an organic material and an inorganic material. In an embodiment, the capping layer 240 may include a transparent conductive oxide (TCO) such as indium zinc oxide (IZO) or indium tin oxide (ITO). However, in an embodiment, the capping layer 240 may be omitted.

An encapsulation layer (not shown) may be disposed on the first to third light-emitting diodes ED1, ED2, and ED3. The encapsulation layer may include at least one inorganic encapsulation layer and at least one organic encapsulation layer. The inorganic encapsulation layer may include at least one inorganic substance among aluminum oxide, titanium oxide, tantalum oxide, hafnium oxide, zinc oxide, silicon oxide, silicon nitride, and silicon oxynitride, and the organic encapsulation layer may include a polymer-based material.

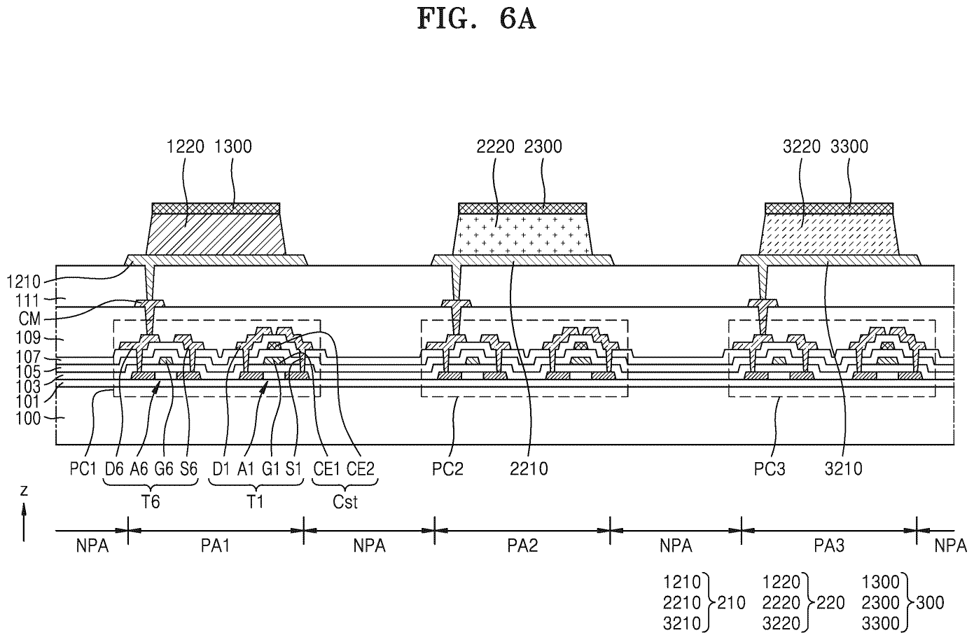

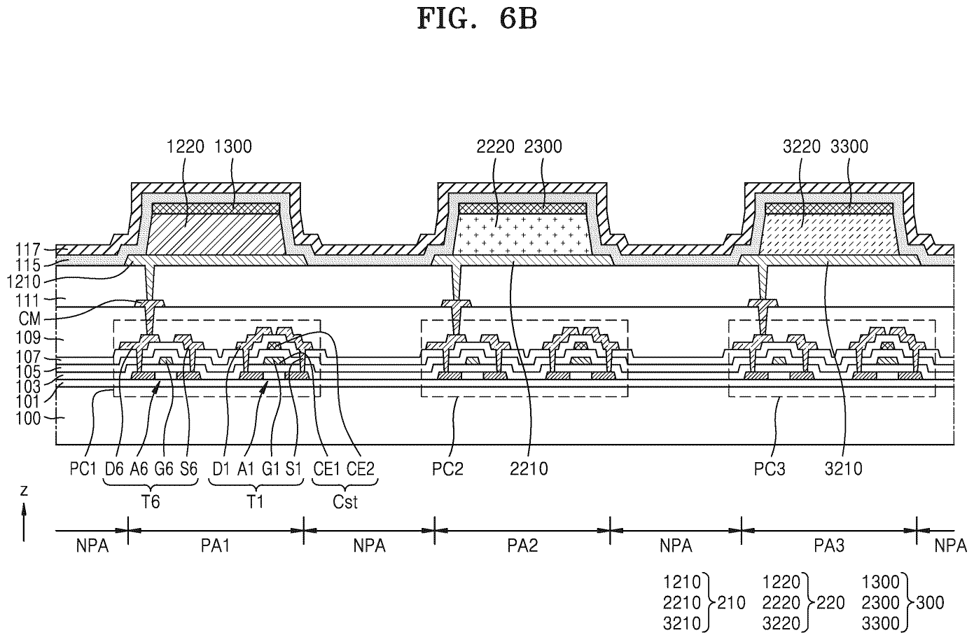

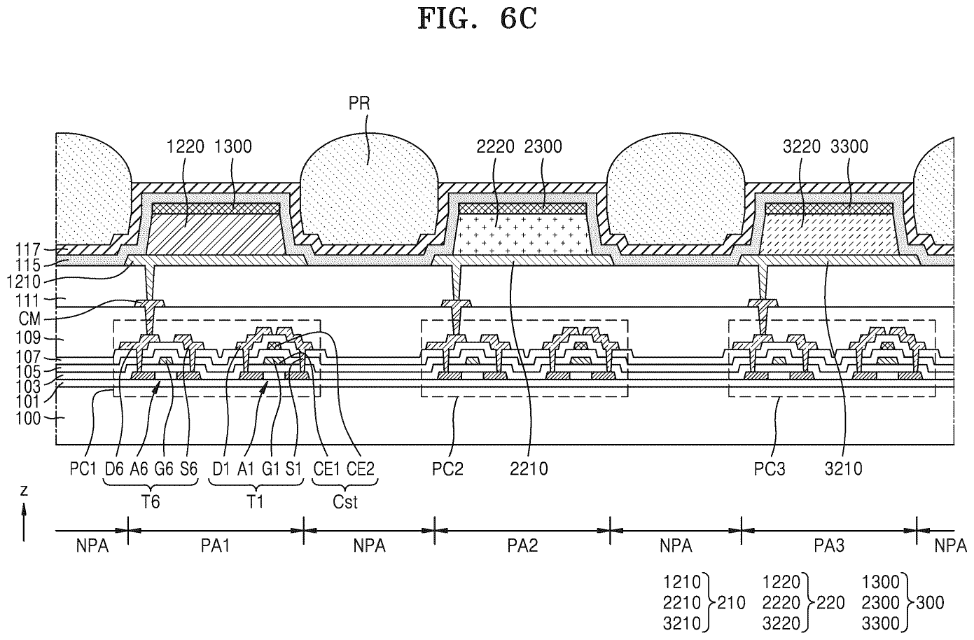

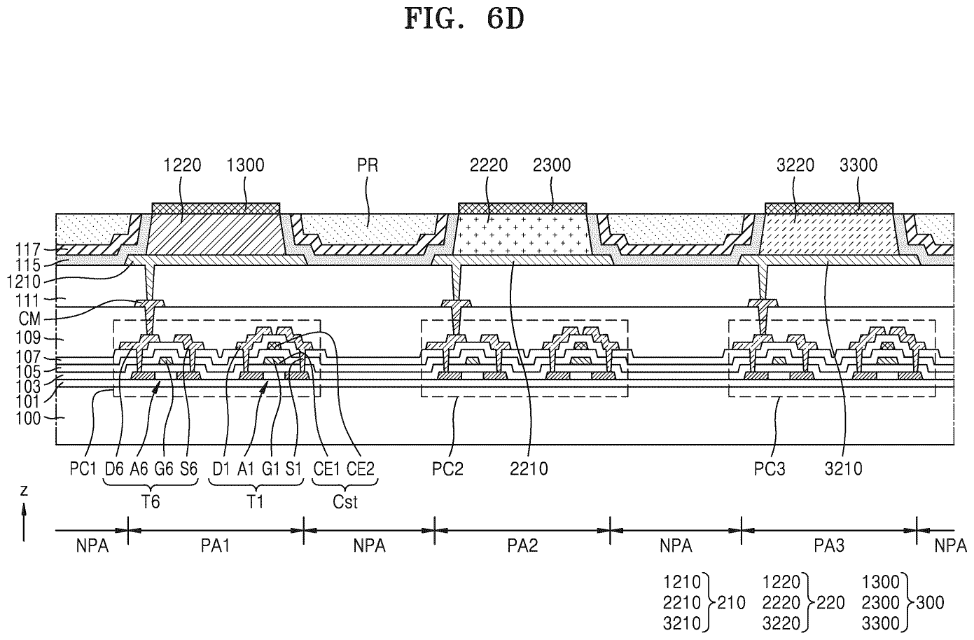

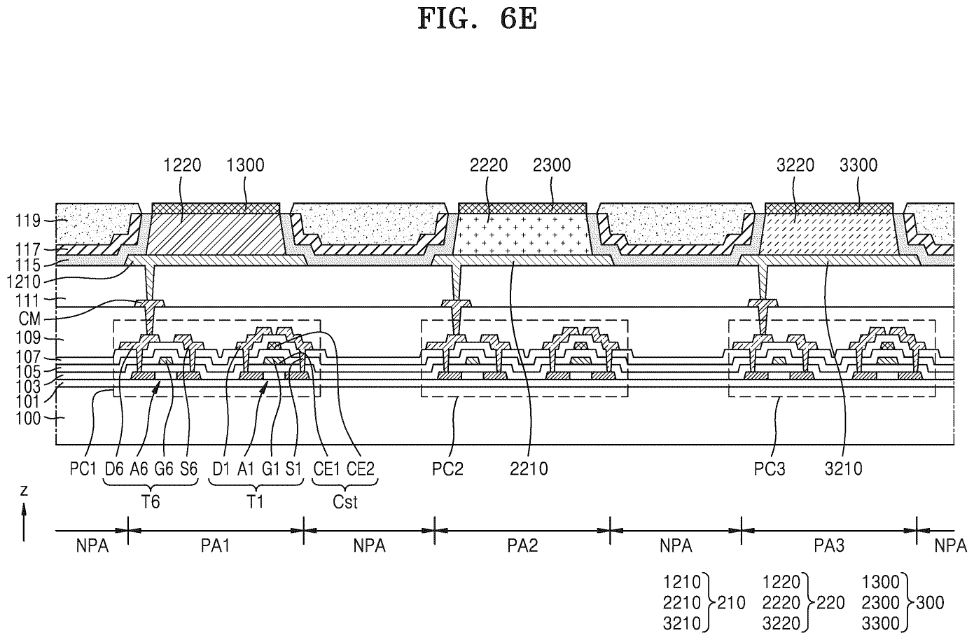

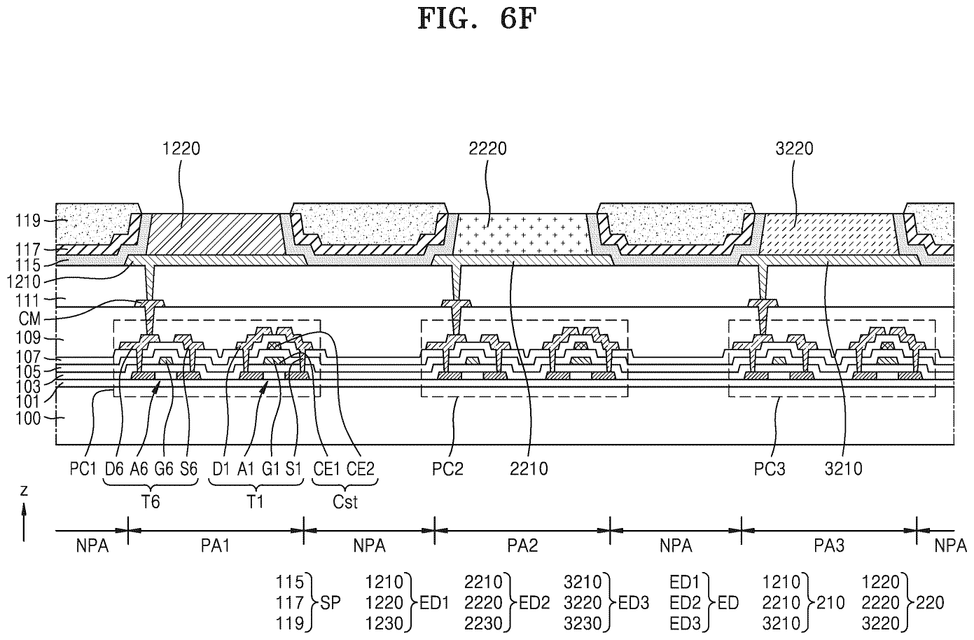

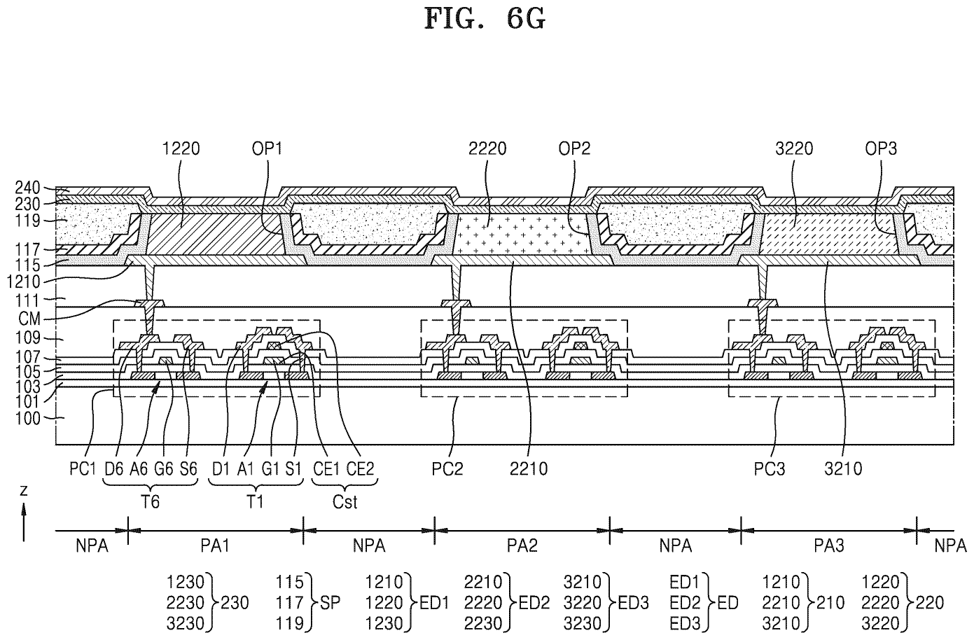

FIGS. 6A to 6P are schematic cross-sectional views showing structures that may be formed during a process of manufacturing a display apparatus according to an embodiment.

First, referring to FIG. 6A, as described above, the display apparatus 1 (see FIG. 4) may include the first to third sub-pixel areas PA1, PA2, and PA3, and the non-sub-pixel area NPA between adjacent sub-pixel areas. The first to third sub-pixel circuits PC1, PC2, and PC3 may be formed on the substrate 100 corresponding to the respective sub-pixel areas. The first to third sub-pixel circuits PC1, PC2, and PC3 may each include transistors and storage capacitors as described above with reference to FIG. 2A and 2B. In the embodiment shown in FIG. 6A, the first to third sub-pixel circuits PC1, PC2, and PC3 each have the same structure as the structure of the first to third sub-pixel circuits PC1, PC2, and PC3 described with reference to FIG. 4, and a specific structure may be the same as that described above.

The first organic insulating layer 109 and the second organic insulating layer 111 may cover the sub-pixel circuit PC, and the first to third sub-pixel electrodes 1210, 2210, and 3210 may be formed on the second organic insulating layer 111. The first to third sub-pixel electrodes 1210, 2210, and 3210 may be respectively connected to the connection metals CM disposed between the first organic insulating layer 109 and the second organic insulating layer 111 and be electrically connected respectively to the first to third sub-pixel circuits PC1, PC2, and PC3. Specifically, the first sub-pixel electrode 1210 may be in the first sub-pixel area PA1 and connected to the first sub-pixel circuit PC1 through the connection metal CM, the second sub-pixel electrode 2210 may be in the second sub-pixel area PA2 and connected to the second sub-pixel circuit PC2 through the connection metal CM, and the third sub-pixel electrode 3210 may be in the third sub-pixel area PA3 and connected to the third sub-pixel circuit PC3 through the connection metal CM.

The intermediate layer 220 may be formed on each sub-pixel electrode 210. The intermediate layer 220 may include the first intermediate layer 1220, the second intermediate layer 2220, and the third intermediate layer 3220, wherein the first intermediate layer 1220 overlaps the first sub-pixel electrode 1210, the second intermediate layer 2220 overlaps the second sub-pixel electrode 2210, and the third intermediate layer 3220 overlaps the third sub-pixel electrode 3210. As described above with reference to FIG. 5, the intermediate layer 220 may have a multi-layer structure including the first common layer, the emission layer, and/or the second common layer.

A protective layer 300 may be formed on the intermediate layer 220. The protective layer 300 may include a first protective layer 1300, a second protective layer 2300, and a third protective layer 3300, wherein the first protective layer 1300 is formed on the first intermediate layer 1220, the second protective layer 2300 is formed on the second intermediate layer 2220, and the third protective layer 3300 is formed on the third intermediate layer 3220. The protective layer 300 may be disposed to prevent damage to the intermediate layer 220, wherein the damage may occur during a subsequent process that forms the spacer SP (see FIG. 4).

In an embodiment, the protective layer 300 may include metal and include a single layer or multiple layers. As an example, the protective layer 300 may include zinc (Zn), indium (In), gallium (Ga), tin (Sn), titanium (Ti), molybdenum (Mo), copper (Cu), or an alloy thereof. However, embodiments are not limited thereto, and the protective layer 300 may include various metal materials. In an embodiment, the protective layer 300 may have a thickness of about 500 Å to about 3000 Å.

A photo patterning process, such as described above, may form the intermediate layer 220 and the protective layer 300. First, to form the first intermediate layer 1220, the first material layer including the same material as that of the first intermediate layer 1220 may be deposited on the entire surface of the substrate 100, and a first protective material layer including the same material as that of the first protective layer 1300 may be deposited on the first material layer. Then, a photoresist may be formed on the first material layer and the first protective material layer to overlap the first sub-pixel electrode 1210. The first intermediate layer 1220 and the first protective layer 1300 may be formed by etching a portion of the first material layer and a portion of the first protective material layer using the photoresist as a mask. The same or similar photo patterning processes may form the second intermediate layer 2220 and the second protective layer 2300 and the third intermediate layer 3220 and the third protective layer 3300.

Next, referring to FIG. 6B, the insulating layer 115 and the light-absorption layer 117 included in the spacer SP (see FIG. 4) may be formed on the structure shown in FIG. 6A. The insulating layer 115 may be disposed on the structure shown in FIG. 6A and be deposited over the entire surface of the substrate 100. Likewise, the light-absorption layer 117 may be disposed on the insulating layer 115 and be deposited over the entire surface of the substrate 100. The materials included in the insulating layer 115 and the light-absorption layer 117 may be the same as those described above with reference to FIG. 4.

Next, referring to FIG. 6C, a photoresist PR may be formed on the structure shown in FIG. 6B. The photoresist PR may be disposed on the light-absorption layer 117 and be arranged in the non-sub-pixel area NPA. In other words, the photoresist PR may be formed in a region in which the first to third intermediate layers 1220, 2220, and 3220 are not arranged. That is, the photoresist PR may be formed to surround each of the first to third intermediate layers 1220, 2220, and 3220 in a plan view and may include openings overlapping the first to third intermediate layers 1220, 2220, and 3220.

Next, referring to FIG. 6D, a portion of the insulating layer 115 and a portion of the light-absorption layer 117 may be removed using the photoresist PR as a mask. As an example, a portion of the insulating layer 115 and a portion of the light-absorption layer 117 may be removed by a dry etching process through the openings in the photoresist PR. The etching process may be performed until the upper surface of the protective layer 300 is exposed. In addition, because the etching process is performed over the entire area of the substrate 100, a portion of the photoresist PR may be removed during the etching process that removes portions of the insulating layer 115 and the light-absorption layer 117 as shown in FIG. 6D.

The insulating layer 115 and the light-absorption layer 117 disposed under the photoresist PR may remain to form portions of the spacer SP (see FIG. 4). The insulating layer 115 may cover the lateral surface of the intermediate layer 220 and extend to cover the edges of the sub-pixel electrode 210. The light-absorption layer 117 may be disposed on the insulating layer 115 and may extend to overlap adjacent intermediate layers 220. As an example, the insulating layer 115 may extend from the lateral surface of the first intermediate layer 1220, through the outer portion of the first sub-pixel electrode 1210, the upper surface of the second organic insulating layer 111, and the outer portion of the second sub-pixel electrode 2210, to the lateral surface of the second intermediate layer 2220. The light-absorption layer 117 may overlap the lateral surface of the first intermediate layer 1220 and extend to also overlap the lateral surface of the second intermediate layer 2220.

Next, referring to FIG. 6E, the photoresist PR may be removed and the bank layer 119 may be formed in a region from which the photoresist PR has been removed. The photoresist PR may be removed through an ashing process. The bank layer 119 may be formed on the light-absorption layer 117 in the non-sub-pixel area NPA. Specifically, the bank layer 119 may be deposited to fill the step difference formed by the intermediate layer 220. In other words, the bank layer 119 may be configured to planarize the upper surface of the structure shown in FIG. 6E. The material included in the bank layer 119 may be the same as that described with reference to FIG. 4. The spacer SP thus formed may include the triple-layer structure of the insulating layer 115, the light-absorption layer 117, and the bank layer 119 shown in FIG. 6E.

Next, referring to FIG. 6F, the protective layer 300 may be removed from the structure shown in FIG. 6E. Because the protective layer 300 includes a metal material, the protective layer 300 may be removed through a wet etching process that selectively etches the metal. An etchant used in the wet etching process of removing the protective layer 300 may not damage the intermediate layer 220. As an example, the etchant used in the etching process for the protective layer 400 may include potassium oxide or tetramethylammonium hydroxide, but the embodiments are not limited thereto.

Next, referring to FIG. 6G, the opposite electrode 230 and the capping layer 240 may be formed on the structure shown in FIG. 6F. The structure shown in FIG. 6F may be heat-cured through a bake process before the opposite electrode 230 and the capping layer 240 may be deposited. The bake process may be performed by applying heat of about 100° C. for about 1 hour.

Each of the opposite electrode 230 and the capping layer 240 may be deposited over the entire surface of the substrate 100. The opposite electrode 230 may be deposited through a thermal deposition process, and the capping layer 240 may be deposited through a sputtering process. Because the spacer SP fills the step difference caused by the intermediate layer 220, each of the opposite electrode 230 and the capping layer 240 may be integrally provided without disconnection. The materials included in the opposite electrode 230 and the capping layer 240 may be the same as those described with reference to FIG. 4.

The display apparatus according to an embodiment may be configured to implement ultra high-resolution images and emit light having color of high purity. However, this effect is an example, and the scope of the disclosure is not limited by this effect.

Embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a first sub-pixel electrode;
a spacer including a first opening overlapping the first sub-pixel electrode, wherein the spacer surrounds the first sub-pixel electrode in a plan view;
a first intermediate layer disposed in the first opening of the spacer and overlapping the first sub-pixel electrode; and
a first opposite electrode disposed on the first intermediate layer,
wherein the spacer includes a structure in which an insulating layer, a light-absorption layer, and a bank layer are sequentially stacked.

2. The display apparatus of claim 1, wherein the insulating layer covers a lateral surface of the first intermediate layer.

3. The display apparatus of claim 2, wherein the insulating layer covers an edge of the first sub-pixel electrode and is in contact with the first opposite electrode.

4. The display apparatus of claim 2, wherein the light-absorption layer covers an upper surface of the insulating layer.

5. The display apparatus of claim 1, wherein an angle formed by the lateral surface of the first intermediate layer with respect to a bottom surface of the first intermediate layer is about 50° to about 90°.

6. The display apparatus of claim 1, further comprising:
a second sub-pixel electrode adjacent to the first sub-pixel electrode;
a second intermediate layer disposed in a second opening of the spacer and overlapping the second sub-pixel electrode; and
a second opposite electrode disposed on the second intermediate layer.

7. The display apparatus of claim 6, wherein the first opposite electrode and the second opposite electrode are integrally provided.

8. The display apparatus of claim 6, wherein the insulating layer and the light-absorption layer extend from a region overlapping a lateral surface of the first intermediate layer to a region overlapping a lateral surface of the second intermediate layer.

9. The display apparatus of claim 8, wherein the bank layer is disposed on the light-absorption layer and fills a step difference formed by the first intermediate layer and the second intermediate layer.

10. The display apparatus of claim 1, wherein the light-absorption layer comprises molybdenum-tantalum oxide (MTO) or molybdenum oxide (MoOₓ).

11. The display apparatus of claim 10, wherein the light-absorption layer has a thickness of about 500 Å to about 3000 Å.

12. The display apparatus of claim 1, wherein the light-absorption layer comprises silicon carbide (SIC).

13. The display apparatus of claim 1, wherein the insulating layer and the bank layer comprise different materials from each other.

14. The display apparatus of claim 13, wherein the insulating layer comprises at least one of silicon nitride (SiNₓ), silicon oxide (SiOₓ), and silicon oxynitride (SiOₓN_{y}).

15. The display apparatus of claim 13, wherein the bank layer comprises at least one of hexamethyldisiloxane (HMDSO) and an acrylic monomer.

16. A method of manufacturing a display apparatus, the method comprising:
forming a first sub-pixel electrode and a second sub-pixel electrode adjacent to the first sub-pixel electrode;
forming a first intermediate layer on the first sub-pixel electrode, and a second intermediate layer on the second sub-pixel electrode;
forming a spacer between the first intermediate layer and the second intermediate layer; and
forming a first opposite electrode on the first intermediate layer, and a second opposite electrode on the second intermediate layer,
wherein the forming of the spacer comprises:
forming an insulating layer covering an edge of the first sub-pixel electrode and an edge of the second sub-pixel electrode;
forming a light-absorption layer on the insulating layer; and
forming a bank layer on the light-absorption layer.

17. The method of claim 16, further comprising, between the forming of the first intermediate layer and the second intermediate layer and the forming of the spacer, forming a first protective layer on the first intermediate layer and a second protective layer on the second intermediate layer.

18. The method of claim 17, wherein the forming of the spacer comprises:
depositing the insulating layer to cover from an upper surface of the first protective layer, through a lateral surface of the first intermediate layer and a lateral surface of the second intermediate layer, to an upper surface of the second protective layer; and
depositing the light-absorption layer on an upper surface of the insulating layer to overlap the upper surface of the first protective layer, the lateral surface of the first intermediate layer, the lateral surface of the second intermediate layer, and the upper surface of the second protective layer.

19. The method of claim 18, wherein the forming of the spacer comprises:
forming a photoresist on the light-absorption layer between the first intermediate layer and the second intermediate layer;
etching a portion of the insulating layer and a portion of the light-absorption layer that do not overlap the photoresist; and
removing the photoresist.

20. The method of claim 19, wherein the bank layer is disposed on the light-absorption layer and is formed to fill a step difference of the first intermediate layer and the second intermediate layer.

21. The method of claim 17, further comprising, between the forming of the spacer and the forming of the first opposite electrode and the second opposite electrode, removing the first protective layer and the second protective layer.

22. The method of claim 16, wherein the first opposite electrode and the second opposite electrode are integrally formed.
